(19) United States
(12) Patent Application Publication
(10) Pub. No.: US 2007/0181914 A1
(43) Pub. Date: Aug. 9, 2007

(54) Non-volatile memory device and method of fabricating the same

(76) Inventors: Jung-sup Uom, Suwon-si (KR); Hyung-moo Park, Seoul (KR); Jae-yoon Noh, Yongin-si (KR); Duk-seo Park, Suwon-si (KR); Jin-kuk Chung, Bupyeong-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/654,637

(22) Filed: Jan. 18, 2007

(30) Foreign Application Priority Data
Jan. 20, 2006 (KR) 10-2006-0006446

(51) Int. Cl. H01L 29/76; H01L 29/745

(52) U.S. Cl. 257/213

(57) ABSTRACT

A non-volatile memory device and method of fabricating same are disclosed. The memory device comprises; a gate insulating film formed on a semiconductor substrate, a floating gate completely covering the gate insulating film, the floating gate comprising a conductive film pattern and a conductive spacer formed at one side of the conductive film pattern, a tunnel insulating film formed on a portion of the conductive film pattern, the conductive spacer, and extending laterally outward over a portion of the semiconductor substrate adjacent the conductive spacer, a control gate formed on the tunnel insulating film, a first impurity region formed within the semiconductor substrate proximate one side of the conductive film pattern opposite the conductive spacer, and a second impurity region formed within the semiconductor substrate proximate one side of the control gate disposed laterally outward from the floating gate.

### BACKGROUND OF THE INVENTION

1. Field of the Invention

The present invention relates to a non-volatile memory device and a method of fabrication. More particularly, the invention relates to a non-volatile memory device having reduced memory cell size and improved electrical characteristics and a method of fabricating same.

This application claims priority from Korean Patent Application No. 10-2006-0006446 filed on Jan. 20, 2006, the subject matter of which is hereby incorporated by reference in its entirety.

2. Description of the Related Art

Generally, non-volatile memory devices can electrically erase and program, and are able to retain stored data even when power is interrupted. As a result of these and other performance advantages, non-volatile memory devices have become a mainstay in the design of many contemporary electronic designs.

Non-volatile memory devices nominally include a source, a drain, a floating gate, an insulating film, and a control gate. In relation to these general components, non-volatile memory devices may be classified into two categories: stack gate type devices in which the floating gate and the control gate are arranged in a stacked configuration; and, split gate type devices in which the floating gate and the control gate are separated from each other.

Split gate type non-volatile memory devices include an independent floating gate per cell. This floating gate is disposed on the left or right side of a common source, assuming a top down perspective of the common source region. In addition, the control gate is disposed so as to partially overlap the semiconductor substrate opposite to the common source and an upper portion of the floating gate. The overlapping portions of the floating gate and control gate are insulated from each other by a tunnel insulating film. In operation, the split gate type non-volatile memory device, data is erased and programmed by means of a channel hot electron injection (CHEI) and the Fowler-Nordheim tunneling effects.

Unfortunately, the independently disposed floating gate component of each memory cell in a conventional split gate type non-volatile memory device inhibits efforts to reduce the per unit cell size. That is, the floating gate components may cause a short circuit between adjacent memory cells when memory cell size shrinks to improve integration density. Further, since a non-volatile memory device implemented with paired memory cells may suffer from certain fabrication process related asymmetry (e.g., misalignment of mask patterns), the performance characteristics for each memory cell may vary in acceptable manners.

### SUMMARY OF THE INVENTION

In one embodiment, the invention provides a non-volatile memory device comprising; a gate insulating film formed on a semiconductor substrate, a floating gate completely covering the gate insulating film, the floating gate comprising a conductive film pattern and a conductive spacer formed at one side of the conductive film pattern, a tunnel insulating film formed on a portion of the conductive film pattern, the conductive spacer, and extending laterally outward over a portion of the semiconductor substrate adjacent the conductive spacer, a control gate formed on the tunnel insulating film, a first impurity region formed within the semiconductor substrate proximate one side of the conductive film pattern opposite the conductive spacer, and a second impurity region formed within the semiconductor substrate proximate one side of the control gate disposed laterally outward from the floating gate.

In another embodiment, the invention provides a method of fabricating a non-volatile memory device, the method comprising; forming a gate insulating film on the semiconductor substrate, forming a floating gate pattern on the gate insulating film, wherein the floating gate pattern comprises a first conductive film pattern and conductive spacers formed on opposing side walls of the first conductive film pattern, patterning the gate insulating film by using the floating gate pattern as an etch mask, sequentially forming a tunnel insulating film and a second conductive film on the semiconductor substrate including the floating gate pattern, forming paired spaced apart control gates on the floating gate pattern, wherein each control gate comprises a portion covering a portion of the first conductive film pattern, one of the conductive spacers, and extending laterally outward over a portion of the semiconductor substrate adjacent the one conductive spacer, and forming a symmetrical pair of floating gates from the floating gate pattern by sequentially etching a portion of the floating gate pattern and the gate insulating film using the paired control gates as an etch mask, forming a first impurity region in the semiconductor substrate between the symmetrical pair of the floating gates, and forming a second impurity region in the semiconductor substrate proximate one side of each control gate disposed laterally outward from the first impurity region.

### BRIEF DESCRIPTION OF THE DRAWINGS

FIG. 1 is a view illustrating a layout of a non-volatile memory device according to an embodiment of the present invention;

FIG. 2 is a cross-sectional view taken along the lines IIA-IIA and IIB-IIB of FIG. 1; and

FIGS. 3 to 7 are cross-sectional views sequentially illustrating processes of fabricating a non-volatile memory device according to another embodiment of the present invention.

### DESCRIPTION OF EMBODIMENTS

Advantages and features of the present invention and methods of accomplishing the same may be understood more readily by reference to the following description of embodiments and the accompanying drawings. The present invention may, however, be embodied in many different forms and should not be construed as being limited to only the embodiments set forth herein. Rather, these embodiments are presented as teaching examples. Throughout the written description and drawings, like reference numerals refer to like or similar elements.

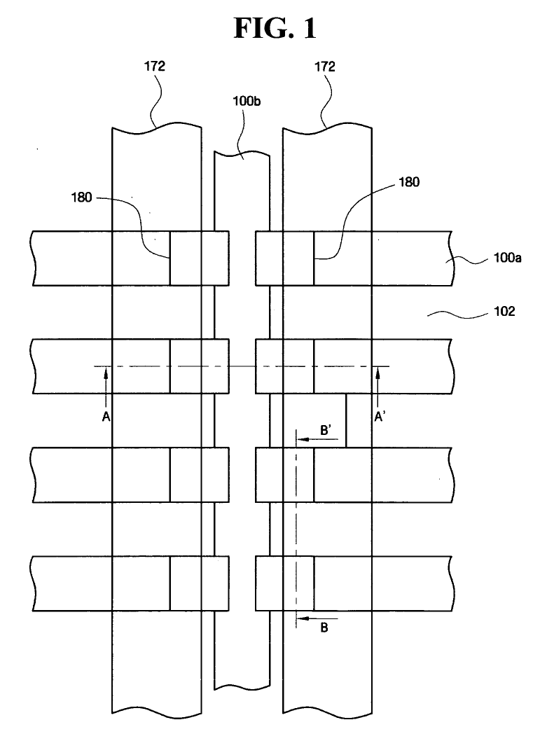

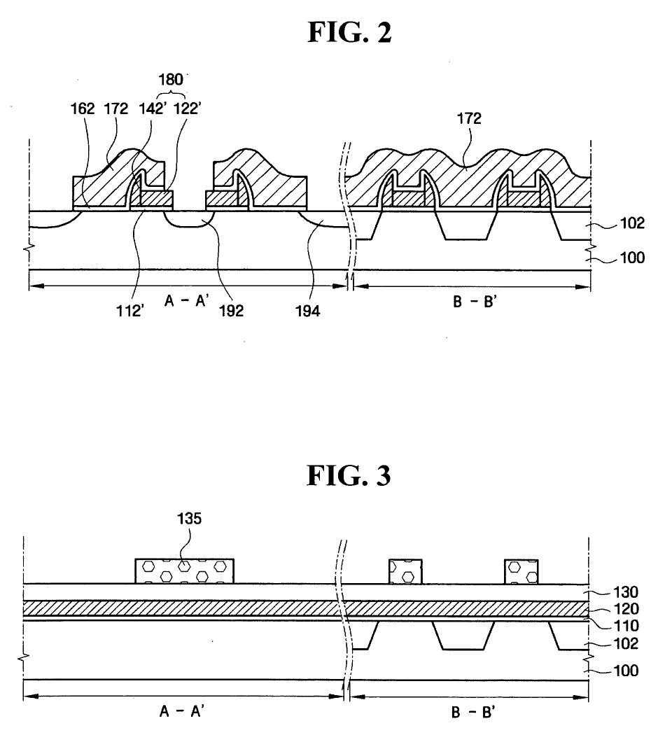

Hereinafter, the structure and operation of a non-volatile memory device according to an embodiment of the present invention will be described with reference to FIGS. 1 and 2.

FIG. 1 is a view illustrating a layout of a non-volatile memory device according to the embodiment of the present invention. FIG. 2 is a cross-sectional view taken along the lines IIA-IIA and IIB-IIB of FIG. 1.

As shown in FIGS. 1 and 2, a semiconductor substrate 100 has a field region and active regions 100a and 100b which are defined by device isolation film 102. Here, semiconductor substrate 100 may be, for example, a silicon substrate, an SOI (Silicon On Insulator) substrate, a gallium-arsenic substrate, a silicon-germanium substrate, a ceramic substrate, a quartz substrate, or a display glass substrate.

Active regions on semiconductor substrate 100 may be classified into a plurality of first active regions 100a and a second active region 100b. The plurality of first active regions 100a are separated from one another in a parallel manner by a predetermined distance. In the illustrated example, second active region 100b orthogonally intersects with the plurality of first active regions 100a.

Asymmetrical pair of memory cells for a non-volatile memory device may be formed on semiconductor substrate 100 in relation to second active region 100b. For example, in one embodiment, a gate insulating film 112′ is selectively formed on predetermined portions of active regions 100a and 100b. A floating gate 180 is then formed on and completely covers the gate insulating film 112′. Floating gate 180 may be formed from laterally disposed conductive film pattern 122′ and conductive spacer 142′. Here, in relation to the symmetrically paired memory cells, respective floating gates 180, as formed from conductive film pattern 122′ and the conductive spacer 142′, are formed on opposite sides of second active region 100b. Conductive spacer 142′ may be formed from the same material as conductive film pattern 122′ and be electrically connected to a side wall portion of conductive film pattern 122′. In the illustrated embodiment, conductive spacer 142′ is formed to a height greater than conductive film pattern 122′ and having a narrow aspect ratio (width to height).

In one more specific embodiment, an insulating film pattern (not shown) may be disposed in a stacked manner on conductive film pattern 122′ of floating gate 180.

The foregoing configuration allows floating gate 180 to include a portion having a pointed geometry (i.e., a “sharp-shaped contour”). Via this sharp-shaped contour (i.e., conductive spacer 142′ in the illustrated example), F-N tunneling effects may be readily induced at a low voltage during an erasing operation applied to the constituent non-volatile memory device.

As floating gate 180 is insulated from neighboring electrodes, during programming operations for the non-volatile memory device, hot electrons move from a drain region 194 to a source region 192. During this operation, the hot electrons pass through gate insulating film 112′ via channel hot electron injection effects and are accumulated on floating gate 180.

A control gate 172 is insulated from and partially disposed over floating gate 180. In read/write operations applied to the constituent non-volatile memory device, control gate 172 connects the memory cell to as associated bit line. In addition, control gate 172 serves as an erase gate during erase operations applied to the non-volatile memory device.

In the illustrated example, control gate 172 covers a portion of conductive film pattern 122′ and completely covers conductive spacer 142′ of floating gate 180. Control gate 172 also extends over a portion of semiconductor substrate 100 adjacent to conductive spacer 142′. That is, control gate 172 conformally extends from a portion of conductive film pattern 122′ over a portion of semiconductor substrate 100 in a direction away from second active region 100b.

Furthermore, a tunnel insulating film 162 is disposed under control gate 172. Tunnel insulating film 162 covers a portion of conductive film pattern 122′, all of conductive spacer 142′, and extends over the portion of semiconductor substrate 100 adjacent to conductive spacer 142′. In this manner, tunnel insulating film 162 is disposed between control gate 172 and most of floating gate 180. Thus, during an erase operation applied to the non-volatile memory device, electrons stored in floating gate 180 pass through tunnel insulating film 162 by the F-N tunneling effects and discharged to control gate 172.

In addition, when symmetrically paired non-volatile memory devices are formed with this structure, they may share a common source region 192 (e.g., as implemented by second active region 100b). The foregoing control gate/floating gate configuration around a common source region allows the formation of size non-volatile memory cells having reduced size.

That is, the paired non-volatile memory device cells are formed with conductive spacer 142′ disposed to one side of conductive film pattern 122′ in a direction away from a common source region. Common source region 192 is disposed in second active region 100b, and respective drain regions 194 are disposed within one of the plurality of first active regions 100a to one side of control gates 172, again in a direction extending away from common source region 192. Drain regions 194 are connected to bit lines (not shown).

In the context of this example, the “direction extending away from the common source region” will hereafter be referred to a “laterally outward.” This designation assumes the use of a centrally located common source region from which paired memory cells extend laterally outward on both sides.

Hereinafter, an exemplary operation of the non-volatile memory device according to an embodiment of the invention will be described with reference to FIG. 2.

First, when a programming operation is applied to the constituent non-volatile memory device, a high voltage is applied to common source region 192 and control gate 172. As a result, a channel is formed between common source region 192 and drain region 194, and electrons generated in drain region 194 are injected onto floating gate 180 by channel hot electron injection (CHEI) effects. During this operation, gate insulating film 112′ serves to raise the electric potential of floating gate 180 by coupling the voltages applied to common source region 192.

Next, an erase operation is applied to the non-volatile memory device, a ground voltage is applied to drain region 194 and common source region 192, and a high voltage is applied to control gate 172. In this manner, an electric field is generated between floating gate 180 and control gate 172. Accordingly, the electrons accumulated on floating gate 180 pass through tunnel insulating film 162 by the F-N tunneling effects and move toward control gate 172. During this operation, tunnel insulating film 162 reduces the coupling ratio between control gate 172 and floating gate 180 so as to keep a potential difference between both ends large.

In addition, during a read operation applied to the non-volatile memory device, a voltage of about 1 to 2 V is applied to control gate 172, a ground voltage is applied to common source region 192, and a voltage of 0.4 to 1 V is applied to drain region 194. Alternatively, a voltage of about 1 to 2 V is applied to control gate 172, a voltage of 0.4 to 1 V is applied to common source region 192, and a ground voltage is applied to drain region 194. Accordingly, if electrons are accumulated on floating gate 180, a channel is not formed between drain region 194 and source region 192, and current will not flow. However, if the electrons are not accumulated on floating gate 180, a channel is formed between drain region 194 and source region 192 and the current flows. As is conventionally understood and assuming the foregoing arrangement, it is possible to sense whether or not electrons are accumulated on floating gate 180 by detecting current flow between drain region 194 and common source region 192. In this manner, stored data may be detected and read from memory.

Hereinafter, a method of fabricating a non-volatile memory device according to another embodiment of the present invention will be described with reference to FIGS. 2 to 7.

FIGS. 3 to 7 are related cross-sectional views sequentially showing an exemplary sequence of fabrication processes applicable to the implementation of a non-volatile memory device according to the embodiment of the invention.

First, as shown in FIG. 3, an element isolation film 102 is formed on semiconductor substrate 100 using an element isolation process adapted to form an array of respectively isolated memory cells. In this manner, device isolation or field regions 102 and active regions may be defined in semiconductor substrate 100. For example, a Local Oxidation of Silicon (LOCOS) process or a Shallow Trench Isolation (STI) process may be used to form the device isolation regions 102.

Also during this process, the active regions of the semiconductor substrate 100 may be further defined as the plurality of first active regions 100a and second active region 100b. As described above with reference to FIG. 1, the plurality of first active regions 100a may be formed in parallel and spaced apart from one another at predetermined intervals, and second active region 100b may be formed to orthogonally intersect the plurality of first active regions 100a.

Following definition of active and isolating regions of semiconductor substrate 100, a gate insulating film 110, a floating gate conductive film 120, and an insulating film 130 may be sequentially formed. Gate insulating film 110 may be formed using a thermal oxidation process to produce a silicon oxidation film (SiO2) having a thickness of between 50 to 150 Å. Floating gate conductive film 120 may be formed from a deposited doped polysilicon layer having a thickness of between about 50 to 150 Å. As is conventionally understood, this polysilicon layer may be doped while being deposited, or by doping a previously deposited polysilicon layer with impurities. A silicon nitride (SiN) film may be used as insulating film 130.

Following sequential formation of these layers, a photo-resist film pattern 135 is formed on insulating film 130. Floating gate conductive film 120 is etched using the photo-resist pattern 135 to form a conductive film pattern 122, and an insulating film 130 is similarly patterned to form an insulating film pattern 132. Sequential etching processes may be applied to accomplish this patterning and substantially expose gate insulating film 110.

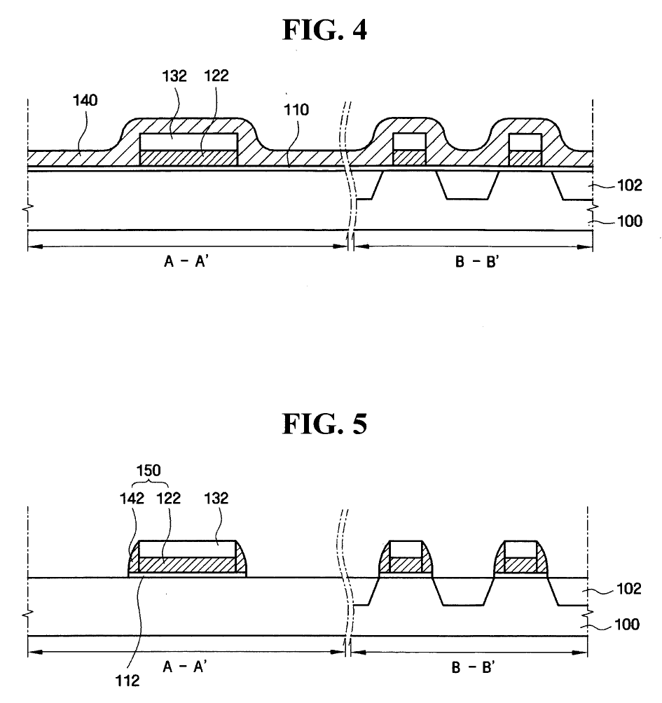

As shown in FIG. 4, conductive spacers 142 may now be formed on both side walls of conductive film pattern 122 and insulating film pattern 132, as stacked on conductive film pattern 122. First, a conductive film 140 is formed over the entire surface of the patterned structure to a thickness of between about 500 to 1500 Å. Conductive film 140 may then be selectively etched to form conductive spacers 142 using a wet or dry etching process. In this manner conductive spacers 142 having a sharp-shaped contour may be formed respective side of conductive film pattern 122. Then, exposed portions of lower gate insulating film 110 may be etched away using a wet or dry etching process. A resulting floating gate pattern 150 completely covers the remaining portion of the lower gate insulting film 110 which serves as gate insulating film 112.

Floating gate pattern 150, as shown in FIG. 5, is thus formed in relation to and in parallel with each one of the plurality of first active regions 100a on semiconductor substrate 100.

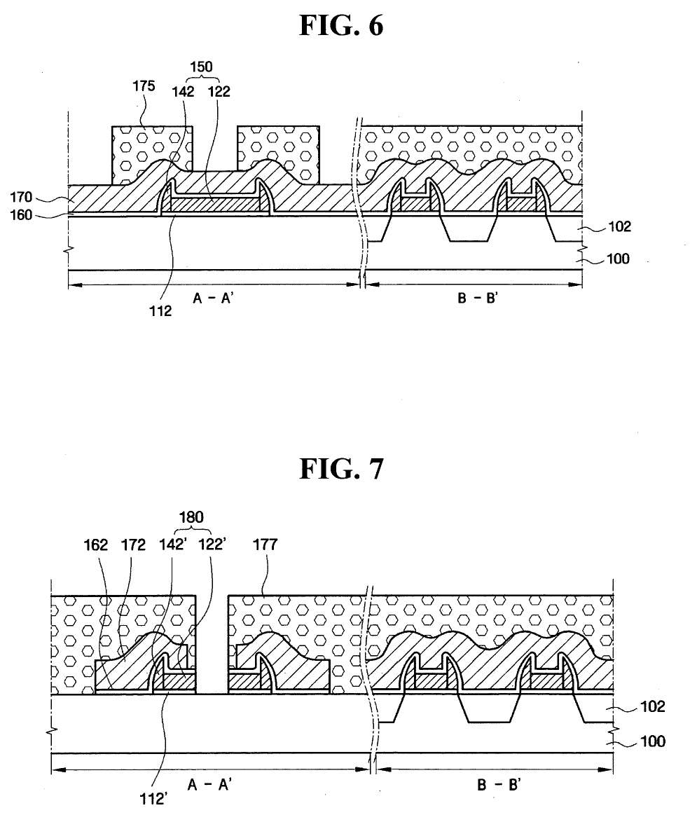

Thereafter, as shown in FIG. 6, a tunnel insulating film 160 and a control gate conductive film 170 are conformably formed over the resulting surface on semiconductor substrate 100, including floating gate pattern 150. Tunnel insulating film 160 may be formed using a thermal oxidation process or a chemical vapor deposition (CVD) process to a thickness of between about 50 to 200 Å. Tunnel insulating film 160 may be formed, for example, using a nitride film, an oxynitride film, a high-k material, and any reasonable combination thereof. Furthermore, a single thin film such as MTO, a multilayer thin film such as a thermal oxidation film/MTO or a thermal oxidation film/SiON/MTO, or an insulating film on which the multilayer thin film may be deposited and treated using N2O-annealing process to form tunnel insulating film 160. Control gate conductive film 170 may be formed from a doped polysilicon layer having a thickness of between about 50 to 2000 Å.

Next, a first mask 175 is formed on control gate conductive film 170 to define the geometry of the control gate. Control gate conductive film 170 and tunnel insulating film 160 are then sequentially etched by using first mask 175. As a result, a pair of control gates 172 are symmetrically formed on floating gate pattern 150. This pair of control gates 172 are spaced apart from one another and the center portion of floating gate pattern 150 is exposed. In this manner a control gate 172 and a corresponding tunnel insulating film 162 are conformably formed over a portion of conductive film pattern 122, conductive spacer 142, and laterally outward over a portion of semiconductor substrate 100 proximate conductive spacer 142.

Next, as shown in FIG. 7, a second mask 177 is formed to expose only a central portion of floating gate pattern 150 between the pair of control gates 172. Then, conductive film pattern 122 and gate insulating film 112 are sequentially etched using second mask 177, to thereby expose second active region 100b of semiconductor substrate 100.

That is, floating gates 180 are formed by dividing floating gate pattern 150 around second active region 100b to complete formation of paired floating gate/control gate structures.

Then, impurities are ion-injected into selected portions of semiconductor substrate 100 by using second mask 177 as an ion-injection mask in order to form common source region 192. In one embodiment, P or As ions are used as the impurities and ion-injected at concentration of about 2E15 to 6E15 ions/cm² with an energy of about 20 to 40 KeV.

Since the impurities are ion-injected with a concentration and energy of significant proportions, the resulting common source region 192 will partially extend underneath each floating gate 180.

Then, second mask 177 is removed, and drain regions 194 are formed on the other side of control gate 172 laterally outward from common source region 192 by ion-injecting impurities into selected portions of semiconductor substrate 100. Drain regions 194 may serve as a bit line junction adapted to connect associated bit lines (not shown).

Although the present invention has been described in connection with the exemplary embodiments, it will be apparent to those skilled in the art that various modifications and changes may be made thereto without departing from the scope of the invention. Therefore, it should be understood that the above embodiments are not limitative, but illustrative.

Using the foregoing fabrication sequence or similar approaches, a non-volatile memory device may be formed according to an embodiment of the invention. An array of memory cells within this non-volatile memory device may be formed without the requirement of an independent mask pattern for each memory cell during the formation of its floating gate. Rather, a pair of floating gates may be formed by dividing a completed floating gate pattern around a common source region. Accordingly, it is possible to shrink the size of the memory cells in the non-volatile memory device without shrinking the size of the mask pattern used to form the floating gate.

Furthermore, since a lower portion of floating gate overlaps the gate insulating film, and the tunnel insulating film under the control gate is formed on the semiconductor substrate, it is possible to improve the electrical characteristics of the non-volatile memory device.

In addition, by forming a floating gate having a portion with a sharp-shaped contour, it is possible to more readily accommodate the migration of electrons during an erase operation applied to the non-volatile memory device.

What is claimed is:

1. A non-volatile memory device comprising:
a gate insulating film formed on a semiconductor substrate;
a floating gate completely covering the gate insulating film, the floating gate comprising a conductive film pattern and a conductive spacer formed at one side of the conductive film pattern;
a tunnel insulating film formed on a portion of the conductive film pattern, the conductive spacer, and extending laterally outward over a portion of the semiconductor substrate adjacent the conductive spacer;
a control gate formed on the tunnel insulating film;
a first impurity region formed within the semiconductor substrate proximate one side of the conductive film pattern opposite the conductive spacer; and
a second impurity region formed within the semiconductor substrate proximate one side of the control gate disposed laterally outward from the floating gate.

2. The non-volatile memory device of claim 1, wherein the conductive spacer has a sharp-shaped contour defined by a height greater than the thickness of the conductive film pattern.

3. The non-volatile memory device of claim 1, wherein the floating gate further comprises an insulating film pattern formed on the conductive film pattern.

4. The non-volatile memory device of claim 3, wherein the conductive spacer is formed at one side of the conductive film pattern and the insulating film pattern.

5. The non-volatile memory device of claim 1, wherein the conductive film pattern and the conductive spacer are formed of a polysilicon.

6. A non-volatile memory device comprising:
a symmetrical pair of floating gate/control gate structures simultaneously formed around a common source region disposed in a semiconductor substrate;
wherein each one of the symmetrical pair of floating gate/control gate structures comprises:
a gate insulating film formed on the semiconductor substrate;
a floating gate completely covering the gate insulating film, the floating gate comprising a conductive film pattern and a conductive spacer formed at one side of the conductive film pattern;
a tunnel insulating film formed on a portion of the conductive film pattern, the conductive spacer, and extending laterally outward over a portion of the semiconductor substrate adjacent the conductive spacer; and
a control gate formed on the tunnel insulating film.

7. The non-volatile memory device of claim 6, wherein the conductive spacer has a sharp-shaped contour defined by a height greater than the thickness of the conductive film pattern.

8. The non-volatile memory device of claim 6, wherein the floating gate further comprises an insulating film pattern formed on the conductive film pattern.

9. The non-volatile memory device of claim 8, wherein the conductive spacer is formed at one side of the conductive film pattern and the insulating film pattern.

10. The non-volatile memory device of claim 6, wherein the conductive film pattern and the conductive spacer are formed of a polysilicon.

11. A method of fabricating a non-volatile memory device, the method comprising:
forming a gate insulating film on the semiconductor substrate;
forming a floating gate pattern on the gate insulating film, wherein the floating gate pattern comprises a first conductive film pattern and conductive spacers formed on opposing side walls of the first conductive film pattern;
patterning the gate insulating film by using the floating gate pattern as an etch mask;
sequentially forming a tunnel insulating film and a second conductive film on the semiconductor substrate including the floating gate pattern;
forming paired spaced apart control gates on the floating gate pattern, wherein each control gate comprises a portion covering a portion of the first conductive film pattern, one of the conductive spacers, and extending laterally outward over a portion of the semiconductor substrate adjacent the one conductive spacer; and
forming a symmetrical pair of floating gates from the floating gate pattern by sequentially etching a portion of the floating gate pattern and the gate insulating film using the paired control gates as an etch mask;
forming a first impurity region in the semiconductor substrate between the symmetrical pair of the floating gates; and
forming a second impurity region in the semiconductor substrate proximate one side of each control gate disposed laterally outward from the first impurity region.

12. The method of claim 11, wherein forming the paired spaced apart control gates on the floating gate pattern comprises sequentially patterning the second conductive film and the tunnel insulating film.

13. The method of claim 12, further comprising:
defining a plurality of first active regions in the semiconductor substrate and a second active region using one or more device isolation regions;
wherein the second active region intersects the plurality of first active regions, the first impurity region is formed in the second active region, and the floating gate pattern is formed within one of the plurality of first active regions.

14. The method of claim 13, wherein the floating gate pattern is formed in parallel with the one first active region.

15. The method of claim 12, wherein the forming of the floating gate pattern comprises:
sequentially forming a first conductive film and an insulating film on the gate insulating film;
patterning the first conductive film and the gate insulating film;
forming a spacer conductive film on the patterned gate insulating film; and
forming the conductive spacers with a sharp-shaped contour by etching back the spacer conductive film until the gate insulating film is exposed.

16. The method of claim 15, further comprising:
removing the insulating film pattern after forming the conductive spacers.

17. The method of claim 15, wherein the first conductive film and the spacer conductive film are formed from the same material.

18. The method of claim 17, wherein the first conductive film and the spacer conductive film are formed from polysilicon.

19. The method of claim 14, wherein the insulating film is formed from an oxidation film or a nitride film.
